(19) United States
(12) Patent Application Publication
(10) Pub. No.: US 2009/0003505 A1
(43) Pub. Date: Jan. 1, 2009

(54) Apparatus and Method for Processing Oscillation Signals in Wireless Communication System Based Tdd

(75) Inventor: Sung-Bae Park, Gyeonggi-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: POSDATA CO., LTD., Seongnam-si (KR)

(21) Appl. No.: 12/160,867

(22) PCT Filed: Jan. 18, 2007
(86) PCT No.: PCT/KR2007/000292

§ 371 Date: Jul. 14, 2008

(30) Foreign Application Priority Data
Jan. 18, 2006 (KR) 10-2006-0005356
Jan. 24, 2006 (KR) 10-2006-007358

(51) Int. Cl. H03D 3/24

(52) U.S. Cl. 375/376; 340/540; 370/280

(57) ABSTRACT

The present invention is an oscillating apparatus and a method for Time Division Duplex (TDD) in a wireless communication system. In a Phase-Locked Loop (PLL) synthesizer applied to the wireless communication system, an oscillation signal generating from a PLL circuit is output by way of an isolation unit in which a capacitor for Direct Current (DC) blocking and a predetermined isolator are combined to form one body. Hence, the oscillation signal isolated from a subsequent circuit through the isolation unit is not affected by the effect of switching noises that flow from a Radio Frequency (RF) switch or into a power amplifier of a transmitter during switching between each Down Link (DL) frame and each Up Link (UL) frame, and therefore the performance of a system can be improved.

### TECHNICAL FIELD

The present invention relates to a wireless communication system, and more particularly to an apparatus and a method for processing an oscillation signal used for an up-conversion of frequency or a down-conversion of frequency in a wireless communication system supporting a Time Division Duplex (TDD) scheme.

### BACKGROUND ART

Recently, in order to realize the fourth-generation mobile communication, in-depth studies are in the process of progressing in all social standings. In the fourth-generation mobile communication according to IEEE 802.16d/e, Wireless Broadband Internet (WiBro), World Interoperability for Microwave Access (WiMAX) standards, and so on, a satellite network, a wireless LAN network, digital audio broadcasting and video broadcasting network, etc., are combined into a single network linked with the parts working in coordinate, and accordingly, a user is now able to be supplied with a harmonious service in a best state, even in any network.

In order to boost the data transfer rate in the fourth-generation mobile communication, the technology of TDD is considered along with the technology of Orthogonal Frequency Division Multiplexing (OFDM). In the technology of TDD, the quantity of data transmission in a Down Link (DL) frame from a base station to a terminal and the quantity of data transmission in an Up Link (UL) frame from the terminal to the base station are asymmetrical to each other. In other words, in order to settle insufficiency of frequency bands in a symmetrical transmission scheme such as the usual technology of Code Division Multiple Access (CDMA), the asymmetrical transmission scheme, such as the technology of TDD, has been considered. For example, in the case of the use of the internet, because the quantity of data that the terminal downloads from a base station in the DL frame is much larger than the amount of data that the terminal uploads to the base station system in the UL frame, as occasion demands when the transfer rate of the DL frame should be increased more than the transfer rate of the UL frame, the technology of TDD can be applied.

In the technology of TDD, as illustrated in FIG. 1, the length of a DL frame can be longer than that of an UL frame, and there exist a Transmit/receive Transition Gap (TTG) and a Receive/transmit Transition Gap (RTG) corresponding to sections for switching between each link. In general, in the case of a base station, a transmitter (Tx) operates during the DL frame, and a receiver (Rx) operates during the UL frame. At this time, by a prescribed Radio Frequency (RF) switch, a local oscillation signal from a Phase-Locked Loop (PLL) is output to a Tx mixer or an Rx mixer, and accordingly, the up-conversion of the frequency in the Tx or the down-conversion of the frequency in the Rx is accomplished. Namely, the local oscillation signal is output to the Rx mixer during the UL frame, and at this time, a Tx circuit is isolated. Also, the local oscillation signal is output to the Tx mixer during the DL frame, and then, an Rx circuit is isolated.

At this time, in a case when the local oscillation signal from the PLL provided through the RF switch fails, the failed local oscillation signal can have a fatal effect on a system, and problems appear in that it is difficult to sense at which position in the circuit constructing the system the failure occurred.

To cite an example, the local oscillation signal becomes a standing wave or can be abnormally output due to a phase change, a frequency vibration or a mixture with other spurious emissions, depending on switching noises, such as a current or a reflected wave, etc., which inversely flow from the RF switch for switching a path of the local oscillation signal during each link frame, and from a power amplifier included in the Tx that ramps up during the DL frame and that ramps down during the UL frame.

Furthermore, the local oscillation signal can be abnormally output to the Tx mixer or the Rx mixer due to the degradation of the PLL circuit or the RF switch. Let us say, in a case where only after passing by the TTG and the RTG due to the delay in the PLL circuit or the delay in the RF switch, etc., the local oscillation signal is normally settled during the UL frame and during the DL frame, a loss of data transmitted/received in the initial stage of each frame can be incurred.

Accordingly, the degradation of the signal such as the rise of a Voltage Standing Wave Ratio (VSWR) or an Error Vector Magnitude (EVM) concerning the local oscillation signal, causes a Packet Error Rate (PER) of the entire system to increase, and even causes a call disconnection.

Since the usual technology of CDMA does not use an RF switch for TDD, the switching noises caused in relation to the RF switch are not generated. Meanwhile, in order to solve a problem of the above switching noises in the technology of TDD, even though there is an attempt such that the local oscillation signal generated in the PLL circuit is delivered to the RF switch via a resistor pad of r-type, etc., and an amplifier, problems appear in that an effect of the attempt is insignificant, and that at this time, an additional circuit causes cost to increase.

### DISCLOSURE OF INVENTION

### Technical Problem

Accordingly, the present invention has been made to solve the above problems occurring in the prior art, and it is an aspect of the present invention to provide an apparatus and a method for processing an oscillation signal in a wireless communication system, which are robust in regard to switching noises with improvement in reducing a pulling factor corresponding to variations of the oscillation signal for TDD according to switching between each DL frame and each UL frame.

It is another aspect of the present invention to provide an apparatus and a method in which an isolation circuit is configured at an output end of a PLL synthesizer from which an oscillation signal for TDD is output, and the oscillation signal is normally and purely generated without being affected by switching noises between each DL frame and each UL frame by using the isolation circuit.

Furthermore, it is another aspect of the present invention to provide an apparatus and a method for easily detecting a failure of an output of an oscillation signal for TDD in a wireless communication system.

It is a further aspect of the present invention is to provide an apparatus and a method in which an alarm detector is configured at an output end of an oscillator for TDD in a wireless communication system, and a failure of an output of the oscillation signal is quickly detected by using the alarm detector when the output of the oscillation signal fails.

### Technical Solution

In accordance with one aspect of the present invention, there is provided an apparatus for processing an oscillation signal in a wireless communication system supporting a Time Division Duplex (TDD) scheme, including: a Phase-Locked Loop (PLL) synthesizer for generating an oscillation signal having a predetermined frequency and being phase-locked by a reference clock signal provided from an oscillator; a Radio Frequency (RF) switch for outputting the oscillation signal to any of a transmission path (Tx) and a receive path (Rx) according to a switch control signal; and an alarm detector for generating an alarm detection signal by using the oscillation signal and a delay signal of the switch control signal, wherein the frequency of a signal transmitted/received in an up link and in a down link is synthesized by using the oscillation signal.

In accordance with another aspect of the present invention, there is provided a method for processing an oscillating signal in a wireless communication system supporting a Time Division Duplex (TDD) scheme, including the steps of: (a) generating an oscillating signal phase-locked to a reference clock signal in a Phase-Locked Loop (PLL) circuit; and (b) isolating the oscillating signal from a signal that flows from an RF switch by using a isolator connected to a capacitor, and outputting the isolated oscillation signal.

### ADVANTAGEOUS EFFECTS

According to the present invention, since a pulling factor is improved so that an oscillation signal from a PLL circuit may not be affected by switching noises such as a current or a reflected wave that flows from an RF switch or from a power amplifier of a transmitter during switching between each DL frame and each UL frame, the oscillation signal is purely and stably provided to a transmission or receive path for the TDD.

Furthermore, according to the present invention, because an output failure of the oscillation signal for the TDD is easily detected, the cause of the degradation of a system is sensed in an early stage, and can be eliminated.

### BRIEF DESCRIPTION OF THE DRAWINGS

The above and other exemplary features, aspects, and advantages of the present invention will be more apparent from the following detailed description taken in conjunction with the accompanying drawings, in which:

FIG. 1 is a view showing sections of UL frame and DL frame in a TDD system;

FIG. 2 is a block diagram illustrating a configuration of an apparatus for processing an oscillation signal of a wireless communication system according to the present invention;

FIG. 3 is a block diagram showing a detailed configuration of a PLL synthesizer illustrated in FIG. 2;

FIG. 4 is a block diagram showing a detailed configuration of a PLL circuit illustrated in FIG. 3;

FIG. 5 is a circuit diagram showing a detailed configuration of a Voltage Controlled Oscillator (VCO) illustrated in FIG. 4;

FIG. 6 is a waveform diagram illustrating a failure of an oscillation signal;

FIG. 7 is a block diagram showing a detailed configuration of an alarm detector illustrated in FIG. 2;

FIG. 8 is a circuit diagram showing an example of a π-pad illustrating FIG. 7; and

FIG. 9 is a timing diagram of signals illustrating an operation of an alarm detector according to the present invention.

### MODE FOR THE INVENTION

Hereinafter, exemplary embodiments of the present invention will be described with reference to the accompanying drawings. The same elements will be designated by the same reference numerals all through the following description and drawings although they are shown in different drawings. Further, in the following description of the present invention, a detailed description of known functions and configurations incorporated herein will be omitted when it may make the subject matter of the present invention rather unclear.

A view for explaining an apparatus 200 for processing an oscillation signal (hereinafter, referred to as “oscillation signal processing apparatus”) in a wireless communication system according to an embodiment of the present invention is illustrated in FIG. 2. With reference to FIG. 2, the oscillation signal processing apparatus 200 includes a processor 210, a PLL synthesizer 220, an RF switch 230, and an alarm detector 240.

The oscillation signal processing apparatus 200 can be applied to a wireless communication system for the fourth-generation mobile communication according to IEEE 802.16d/e, WiBro, WiMAX standards, etc. Above all, in a TDD system that transmits data symmetrically or unsymmetrically in a Down Link (DL) frame from a base station to a terminal and in an Up Link (UL) frame from the terminal to the base station, and that improves a data transfer rate, in order to output a local oscillation signal LO normally and purely during each link frame, the oscillation signal processing apparatus 200 has been proposed. The oscillation signal processing apparatus 200 in the present invention prevents the local oscillation signal LO from being abnormally output by the effect of switching noises generated while being switched between each link frame. Specially, in a portable internet system that transmits/receives huge amounts of data at a high rate, and that uses a TDD scheme, the oscillation signal processing apparatus 200 performs an important role such that the oscillation signal processing apparatus 200 prevents the local oscillation signal LO from being abnormally output due to a phase change, a frequency vibration or a mixture with other spurious emissions by the effect from a subsequent circuit.

The local oscillation signal LO (hereinafter, referred to as “oscillation signal”) is generated by a PLL synthesizer 220 that uses a reference clock signal REF. Particularly, so that the oscillation signal LO may be purely and normally output during the switching of the RF switch 230, the PLL synthesizer 220 isolates the oscillation signal LO from the effect of switching noises such as a current or a reflected wave, etc., which inversely flow from a power amplifier (not shown) included in a transmitter and from the RF switch 230 for switching a path of the oscillation signal during each link frame, and outputs the isolated oscillation signal.

The oscillation signal LO provided from the PLL synthesizer 220 with isolation from the switching noises is selectively output to any of a transmission path and a receive path according to a switch control signal SWS in the RF switch 230. The switch control signal SWS is generated by the processor 210. The processor 210 can correspond to a MOdulator/DEModulator (MODEM) in a usual wireless communication system. The oscillation signal LO output from the RF switch 230 is used to synthesize the frequency of a signal transmitted/received in an UL frame and in a DL frame for the TDD. For instance, during a DL frame, the oscillation signal LO is output to the transmission path (Tx), and a signal that has been modulated according to a prescribed modulation scheme is synthesized with the oscillation signal LO in a mixer of a transmitter circuit, and can be converted into a carrier signal. Also, during an UL frame, the oscillation signal LO is output to the receive path (Rx), and an RF signal received from the base station is synthesized with the oscillation signal LO in a mixer of a receiver circuit, and can be converted into a baseband signal.

A detailed block diagram of the PLL synthesizer 220 is illustrated in FIG. 3. Referring to FIG. 3, the PLL synthesizer 220 includes a PLL circuit 360 and an isolation unit 370.

The PLL circuit 360 generates an oscillation signal LT oscillating with a pre-determined frequency from a reference clock signal REF provided from a crystal oscillator. The oscillation signal LT provided by the PLL circuit 360 is output while being phase-locked to the reference clock signal REF.

So that the isolation unit 370 may isolate the oscillation signal LT provided by the PLL circuit 360 from the effect of a subsequent circuit to output the isolated oscillation signal LT, the isolation unit 370 uses an isolator 371 coupled to a capacitor C1. The isolation unit 370 isolates the effect of the switching noises that flow from the RF switch 230 used during the switching between the UL frame and the DL frame for the TDD. As stated above, the switching noises can appear in the form of the reflected wave, which is a current or voltage inversely flowed from the transmitter circuit including the power amplifier (not shown) or inversely flowed from the RF switch 230 during the switching of the RF switch 230, or other spurious noises, etc.

In order to shut off the above switching noises, the capacitor C1 blocks a Direct Current (DC) signal that inversely flows from the RF switch 230, and the isolation unit 370 can have the form of an element matched to the DC blocking capacitor C1 in order to form one body so that magnetic substance for the isolator 371 may have a prescribed capacitance between an input and an output.

The magnetic substance for the isolator 371 has a large resistance value and a large Faraday's rotation angle. A barium ferrite substance or a strontium ferrite substance that has a high coercivity can be used as the magnetic substance for the isolator 371. Accordingly, the isolator 371 operates as a non-reversible two terminal passive circuit element, transmits an input signal without attenuation only in a direction from an input terminal to an output terminal, and shuts off a signal that inversely flows from the output terminal. So that a predetermined capacitance for additional DC blocking exists between an input and an output of the ferrite substance for the isolator 371, the DC blocking capacitor C1 and the isolator 371 are manufactured to form one body, which can be used as the isolation unit 370.

Herein, so that the isolator 371 may be manufactured to form one body with the DC blocking capacitor C1, the isolator 371 is desirably a two terminal element. However, the isolator 371 is not limited to this, and can have the form such as a circulator having three terminals including one input and two outputs. Then, a matched load can be used to connected to the remaining unnecessary output terminals.

In addition, the DC blocking capacitor C1 and the isolator 371 are desirably manufactured to form one body. However, the DC blocking capacitor C1 and the isolator 371 are not limited to this, and the isolation unit 370, as illustrated in FIG. 3, can have the form such that the DC blocking capacitor C1 is serially connected to the isolator 371 by an element for special purpose, or such that the DC blocking capacitor C1 is connected with the isolator 371 in parallel.

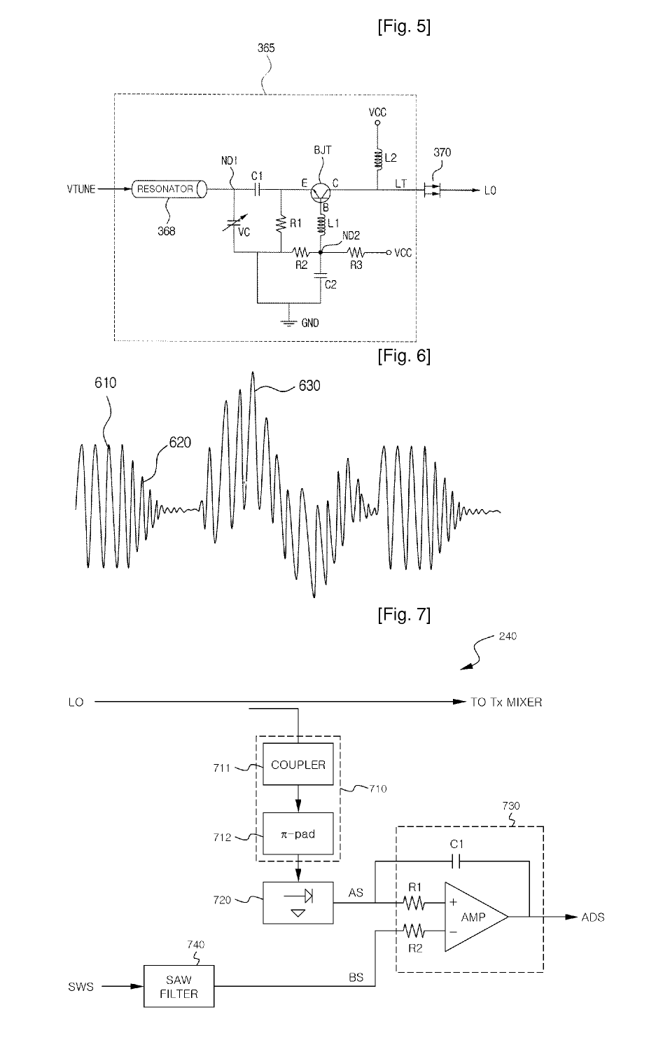

FIG. 4 is a block diagram showing a detailed configuration of a PLL circuit 360 according to an embodiment of the present invention. As illustrated in FIG. 4, the PLL circuit 360 includes a first frequency divider 361, a Phase Comparator (PC) 362, a Charge Pump (CP) 363, a Loop Filter (LF) 364, a Voltage Controlled Oscillator (VCO) 365, and a second frequency divider 366.

The first frequency divider 361 divides a frequency of a first signal by a pre-determined rate R, which generated as a reference clock signal REF from a crystal oscillator, etc., and outputs a frequency-divided signal to the PC 362. In a case where the reference clock signal REF has the frequency suited to a system, the first frequency divider 361 cannot be used, and then, the reference clock signal can be directly output to the PC 362.

The PC 362 compares a phase of a second signal that is obtained by dividing an oscillation signal LT generated from the VCO 365 by a predetermined ratio N in the second frequency divider 366, with a phase of an output signal (or the reference clock signal REF) from the first frequency divider 361, and generates a phase difference signal between the two signals. The CP 363 controls the quantity of output electric charges according to the phase difference signal. The phase difference signal can be divided into an up signal and a down signal that can be output. Hence, the CP 363 can increase the quantity of output electric charges by the up signal, and can reduce the quantity of output electric charges by the down signal. According to the operation of CP 363 in this way, the LF 364 performs low-pass filtering on an output from the CP 363, and generates a frequency tuning voltage VTUNE. Therefore, the VCO 365 produces an oscillation signal LT which has a predetermined frequency and is phase-locked to the reference clock signal REF, according to the frequency tuning voltage VTUNE generated from the LF 364.

The relation between the VCO 365 and the isolation unit 370 is illustrated in FIG. 5. With reference to FIG. 5, the VCO 365 includes a resonator 368, a varactor VC, capacitors C1 and C2, inductors L1 and L2, a Bipolar Junction Transistor BJT, and resistors R1, R2, and R3. The isolation unit 370 is located outside the VCO 365, and isolates the output LT of the VCO 365. However, it is also possible to construct the VCO 365 to include the isolation unit 370.

In FIG. 4, the frequency tuning voltage VTUNE generated from the LF 364 is delivered to a node ND1 through the resonator 368, and the varactor VC is connected between the node ND1 and a ground GND. Herein, the resonator 368 can be a microstrip line that has a predetermined inductance L and a predetermined capacitance C in connection with a board.

According to the frequency tuning voltage VTUNE delivered to the node ND1 by way of the resonator 368, the capacitance of the varactor VC is varied, and accordingly, a signal that oscillates with a predetermined frequency necessary for the system can be output at a collector C of the bipolar junction transistor BJT.

So that a signal oscillating with the predetermined frequency may be output at the collector C of the bipolar junction transistor BJT, an L-C circuit having the inductors L1 and L2, and the capacitors C1, C2, and C3 are used. Also, the resistors R1, R2, and R3 are used to apply an adequate bias to each node among configuration elements.

The capacitor C1 is connected between the node ND1 and an emitter E of the bipolar junction transistor BJT. The resistor R1 is connected between the emitter E of the bipolar junction transistor BJT and the ground GND. The inductor L1 is connected between a base B of the bipolar junction transistor BJT and a node ND2. The resistor R2 is connected between the node ND2 and the ground GND. The capacitor C2 is also connected between the ND2 and the GND. The resistor R3 is connected between a power source VCC and the node ND2. The inductor L2 is connected between the collector C of the bipolar junction transistor BJT and the power source VCC.

If the VCO 365 having the circuit configuration as illustrated in FIG. 5 generates a signal LT oscillating with a predetermined frequency according to the frequency tuning voltage VTUNE, the generated signal LT is delivered to the RF switch 230 illustrated in FIG. 2 by way of the isolation unit 370.

In this manner, an oscillation signal LO from the isolation unit 370 is output to a transmission path (Tx) or a receive path (Rx) through the RF switch 230, and is used to synthesize frequency of a signal transmitted/received in an UL frame or in a DL frame.

At this time, the effect of a reflected wave or other spurious noises that inversely flow from the RF switch 230 during the switching of the RF switch 230 is isolated by the isolation unit 370. Also, in a TDD system using the RF switch 230, the effect that can be given to the oscillation signal LO through the RF switch 230 by a large current or voltage, which inversely flows from the power amplifier due to ramp up/down of the power amplifier (not shown) of the transmitter, can be isolated by the isolation unit 370.

In a case where the oscillation signal is affected by the switching noises that inversely flow from the RF switch 230 or from the transmitter circuit in this manner, the PLL circuit 360 needs much time to perform the phase-locking. Hereupon, especially, a signal provided by the VCO 365 cannot oscillate with a predetermined frequency, and becomes a standing wave or can be abnormally output due to a phase change, a frequency vibration or a mixture with other spurious emissions.

For example, even though the oscillation signal LO that is not only pure but also oscillates with a fixed frequency as 610 illustrated in FIG. 6, the phase change, the frequency vibration, etc., can appear as 620 due to the switching noises, and low frequency noise or a DC level can be output as the DC level itself changes like 630.

In this manner, in the present invention, the isolation unit 370 isolates the effect of the switching noises that flow from a subsequent circuit during the switching between each DL frame and each UL frame, which enables the oscillation signal LT oscillating with a predetermined frequency to be easily phase-locked to the reference clock signal REF and to be output, in the PLL circuit 360. Accordingly, as the oscillation signal LO output through the isolation unit 370 is always purely and normally output, a pulling factor can be improved, and a wireless communication system can be realized which is robust against the switching noises.

Furthermore, in the PLL synthesizer 220 according to an embodiment of the present invention, the oscillation signal LT generated by the PLL circuit 360 is output through the isolation unit 370 in which the DC blocking capacitor C1 and the isolator 371 are combined to form one body. Hereupon, the oscillation signal LO isolated from a subsequent circuit by the isolation unit 370 is not affected by the switching noises that flow from the RF switch 230 or from the power amplifier (not shown) of a transmitter during the switching between each DL frame and each UL frame, and therefore, the performance of the system can be improved.

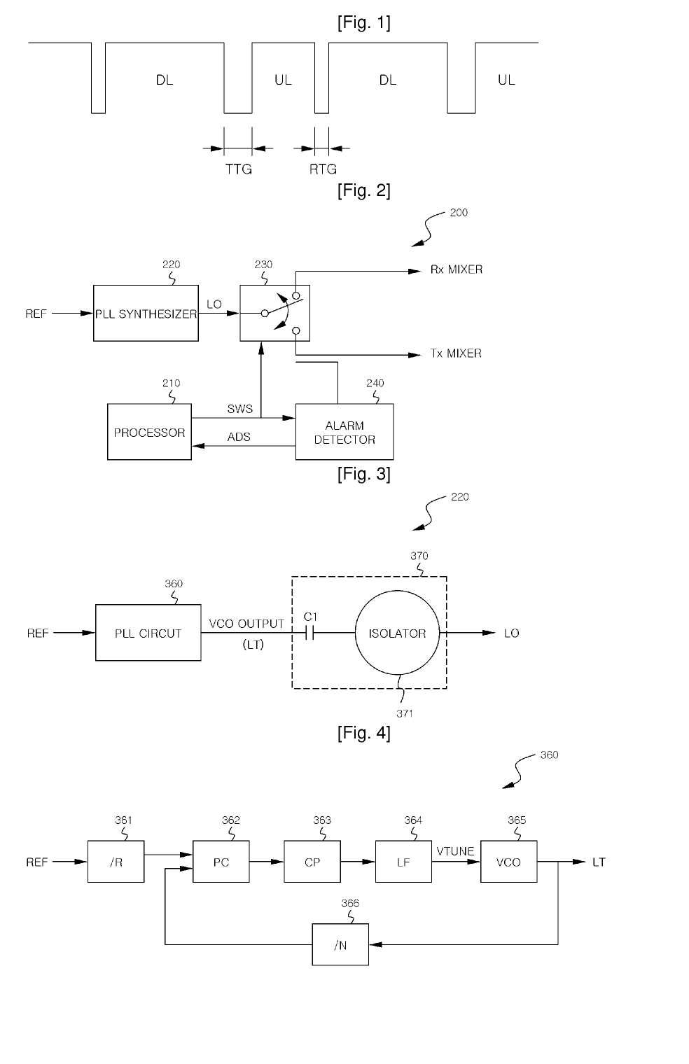

Meanwhile, in the TDD scheme as previously stated, besides a delay in the PLL synthesizer 220 itself or in the RF switch 230 itself, due to the degradation of the above circuits, the oscillation signal LO is more delayed, and is output abnormally. Only after passing by a TTG and an RTG (refer to FIG. 1) because of a failure of the oscillation signal LO as described above, the oscillation signal LO can be normally settled during the UL frame and during the DL frame. At this time, a Packet Error Rate (PER) can be increased or a loss of data transmitted/received in the initial stage of each link frame can be incurred. Moreover, in a serious case where the oscillation signal LO is not output at all but has only the DC ingredients, a call itself can be disconnected.

In order to detect the failure of the oscillation signal LO selected and provided by the RF switch 230 as illustrated in FIG. 2, an alarm detector 240 is used. The alarm detector 240 induces the oscillation signal LO output from the RF switch 230, and produces an Alarm Detection Signal (ADS) from a signal obtained by converting the induced oscillation signal LO into a Direct Current (DC) level, and from a signal corresponding to a delayed switch control signal SWS. As described in an illustration of FIG. 7, the switch control signal SWS is delayed by a delay value determined based on a time interval (refer to ST illustrated in FIG. 9) for which the oscillation signal LO passes by the RF switch 230, and is settled as a normal signal. Furthermore, the alarm detector 240 converts the induced oscillation signal LO into a predetermined DC level, and detects how an integration signal of a signal converted into the DC level is output according to the signal corresponding to the delayed switch control signal SWS. The alarm detector 240 will be described in further detail with reference to FIG. 7 as in the following.

Accordingly, the processor 210 samples the alarm detection signal ADS, and can determine if the oscillation signal LO provided by the RF switch 230 is normal. The processor 210 samples the alarm detection signal ADS during the UL frame or during the DL frame except for gaps (i.e., TTG/RTG) among the link frames. For instance, as showed in FIG. 9, in a case where the alarm detection signal ADS is active in a high logic state during the DL frame, when the processor 210 samples the alarm detection signal ADS during the DL frame, particularly, in the initial stage of the DL frame, if sampling a logic high state, it is determined that the alarm detection signal ADS is normal. If not, it is determined that the alarm detection signal ADS is failed.

Likewise, in order to detect a failure of the oscillation signal LO provided from the RF switch 230 to the receive path (Rx) during the UL frame, the alarm detector 240 can also induce the oscillation signal LO from the receive path (Rx). However, because the quantity of transmission data is larger during the DL frame than during the UL frame, it is more desirable that the alarm detector 240 induces the oscillation signal LO from the transmission path (Tx).

FIG. 7 is a block diagram showing a detailed configuration of an alarm detector 240 illustrated in FIG. 2. Referring to FIG. 7, the alarm detector 240 includes a signal inducing unit 710 equipped with a coupler 711 and a π-pad 712, an RF detecting unit 720, a comparing unit 730, and Surface Acoustic Wave (SAW) filter 740.

In FIG. 7, it is assumed that the alarm detector 240 induces the oscillation signal LO from the transmission path (Tx).

The signal inducing unit 710 induces the oscillation signal LO which flows from the RF switch 230 into the transmission path (Tx). By using a microstrip line arranged so as to lie adjacent to a conducting wire through which the oscillation signal LO passes, the coupler 711 of the signal inducing unit 710 induces a signal from the oscillation signal LO which passes the transmission path (Tx) or the receive path (Rx), wherein the induced signal flows into the coupler 711 as being coupled and copied with oscillation signal LO. The induced oscillation signal LO flowing into the coupler 711 is filtered by the π-pad 712. Noises can be mixed in the induced oscillation signal LO flowing into the coupler 711, but the noises can be removed by the π-pad 712.

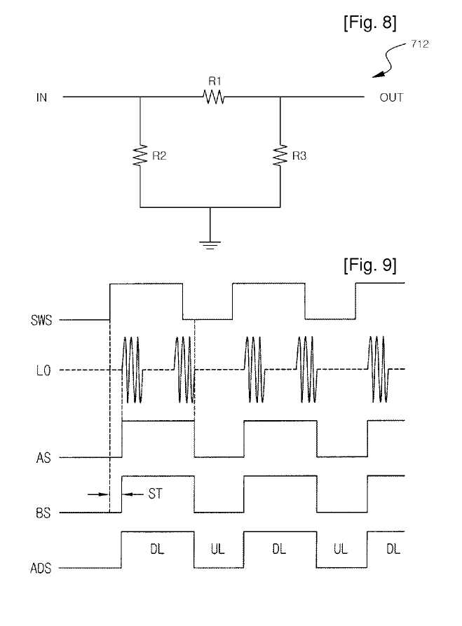

With reference to FIG. 8, the π-pad 712 has resistors R1, R2, and R3 arranged in the π form among an input, an output, and the ground GND of the signal flowing into the coupler 711. Even though the π-pad 712 is necessary to remove the noises, in a case where the signal flowing into the coupler 711 is pure, the π-pad 712 corresponds to the option that cannot be used.

The RF detecting unit 720 converts the oscillation signal LO induced by the signal inducing unit 710 into a DC level signal. The RF detecting unit 720 clips the induced oscillation signal LO at a predetermined level by using a Schottky diode that conducts an input to an output if an applied voltage is more than a threshold voltage, and can produce a relevant DC signal AS like in FIG. 9 in the way of low-pass filtering of a clipped oscillation signal LO. Then, in the case where the induced oscillation signal LO corresponds to a normal oscillation signal, the DC level of the output signal AS from the RF detecting unit 720 is shown on a large scale, whereas the DC level of the output signal AS of the RF detecting unit 720 can be shown in a small size in a case where the induced oscillation signal LO corresponds to a naught signal or is delayed. As the RF detecting unit 720, an RF detector element can be used which outputs a pre-determined DC level signal according to the peak-to-peak level of a predetermined input high frequency signal.

The SAW filter 740 delays the switch control signal SWS from the processor 210, and outputs a delayed switch control signal. As previously stated, the switch control signal SWS is provided to the RF switch 230 for the TDD, and enables the oscillation signal LO to be selectively output to either the transmission path (Tx) or the receive path (Rx) according to the switch control signal SWS in the RF switch 230. Herein, the switch control signal SWS has the form of a binary logic signal as illustrated in FIG. 9. To give an example, in a case when the switch control signal SWS is in a high logic state, the oscillation signal LO is output to the transmission path (Tx), and the oscillation signal LO can be output to the receive path (Rx) in a case when the switch control signal SWS is in a low logic state.

In this manner, since the switch control signal SWS for controlling the RF switch 230 has a high frequency in a system for high-speed wireless communications such as WiBro, WiMAX, etc., the switch control signal SWS can include glitches or other unnecessary spurious noises. At this time, the SAW filter 740 for delivering a signal by using a physical vibration by the surface acoustic waves, group-delays the switch control signal SWS by a predetermined quantity, and simultaneously, eliminates certain noises from the switch control signal that is to be output.

The selected quantity by which the SAW filter 740 delays the switch control signal SWS is determined based on a time interval (refer to ST illustrated in FIG. 9) for which the oscillation signal LO passes by the RF switch 230, and is settled as a normal signal. For example, when transitioning from an UL frame to a DL frame, the Settling Time ST can be determined by considering both a time interval for which the oscillation signal LO provided from the PLL synthesizer 220 is stabilized and a delay caused when the oscillation signal LO passes through the RF switch 230.

Hence, the comparing unit 730 generates an Alarm Detection Signal ADS from the output AS of the RF detecting unit 720 and the output BS of the SAW filter 740.

As shown in FIG. 7, the comparing unit 730 can include resistors R1 and R2, an amplifier {e.g., OPerational AMPlifier (OP AMP)}, and a capacitor C1. One terminal of the resistor R1 is connected to an output end of the RF detecting unit 720, and the other terminal is connected to one input terminal {e.g., a (+) terminal} of the amplifier OP AMP. One terminal of the resistor R2 is connected with an output end of the SAW filter 740, and the other terminal is connected with the other input terminal {e.g., a (−) terminal}. The capacitor C1 is connected between the output end of the RF detecting unit 720 and an output end of the amplifier OP AMP. On this account, the amplifier OP AMP receives signals, which go through the resistors R1 and R2, at the two input terminals (+) and (−), and provides the alarm detection signal ADS to the output end. Namely, in a case where the output BS of the SAW filter 740 is active into a high logic state, the amplifier OP AMP integrates the output AS from the RF detecting unit 720, and outputs an integrated signal as the alarm detection signal ADS.

Thus, if the oscillation signal LO provided from the RF switch 230 is normal, the alarm detection signal ADS is shown as more delayed by ST than the switch control signal SWS, and is shown as having its logic state whose transition is implemented simultaneously with a logic state of the output AS from the RF detecting unit 720 or with a logic state of the output BS from the SAW filter 740.

If the oscillation signal LO provided from the RF switch 230 appears as a naught signal having only DC ingredients or as in an abnormal form having other delays of a large scale, in an example illustrated in FIG. 9, the alarm detection signal ADS is output in a low logic state even during the DL frame, or is shown with a delay that is longer than the settling time ST despite the appearance in a high logic state during the DL frame.

According to the alarm detection signal ADS detected in this manner, the processor 210 samples the alarm detection signal ADS, and can determine if the oscillation signal LO provided by the RF switch 230 is normal. In a case where the oscillation signal LO provided by the RF switch 230 is abnormal due to the degradation of the RF switch 230 or the PLL synthesizer 220, a signal sampled during the DL frame other than the gap (i.e., the TTG or the RTG) between each link frame has a low logic state, and at this time, the oscillation signal LO provided by the RF switch 230 can be determined as failed. With reference to FIG. 9, it is desirable that the comparing unit 730 is configured so that the alarm detection signal ADS may have a low logic stare in the gap (i.e., the TTG or the RTG) between each link frame.

Similarly, in a case when a signal sampled during the DL frame has a high logic state, it is determined that the output of the oscillation signal LO is normal. The result of the determination like this can be output in the form of a certain flag signal, and can be displayed through Light Emitting Diodes (LEDs) or other display devices.

In FIGS. 7 and 9, an example in which it is determined whether the oscillation signal LO is normal during the DL frame, is described. However, those skilled in the art can construct a system, as aforementioned, in order to determine if the oscillation signal LO provided by the RF switch 230 during the UL frame by the alarm detector 240 disposed in the receive path (Rx) is normal.

As previously stated, in the alarm detector 240 according to an embodiment of the present invention, the RF detecting unit 720 converts the oscillation signal LO induced by the signal inducing unit 710 into a DC level to output the DC level, and if the SAW filter 740 delays the switch control signal SWS to output the delayed switch control signal, the comparing unit 730 produces the alarm detection signal ADS from the output AS of the RF detecting unit 720 and from the output BS of the SAW filter 740.

Meanwhile, functions used in an apparatus and a method disclosed in the present specification can be embodied in storage media that a computer can read as codes that the computer can read. The storage media that the computer can read, include all sorts of record devices in which data that can be read by a computer system is stored. Examples of the storage media that the computer can read, include ROMs, RAMs, CD-ROMs, magnetic tape, floppy discs, optic data storage devices, etc., and also, include things embodied in the form of carrier wave (e.g., transmission through the internet). Furthermore, the storage media that the computer can read is distributed in a computer system connected with networks. Then, the codes that the computer can read, are stored in the distributed storage media in a distribution scheme, and the codes can be executed in the distribution scheme.

While the invention has been shown and described with reference to certain exemplary embodiments thereof, it will be understood by those skilled in the art that various changes in form and details may be made therein without departing from the spirit and scope of the invention. Therefore, the spirit and scope of the present invention must be defined not by described embodiments thereof but by the appended claims and equivalents of the appended claims.

1. An apparatus for processing an oscillation signal in a wireless communication system supporting a Time Division Duplex (TDD) scheme, the apparatus comprising:
a Phase-Locked Loop (PLL) synthesizer for generating an oscillation signal having a predetermined frequency and being phase-locked by a reference clock signal provided from an oscillator;
a Radio Frequency (RF) switch for outputting the oscillation signal to any of a transmission path (Tx) and a receive path (Rx) according to a switch control signal; and
an alarm detector for generating an alarm detection signal by using the oscillation signal and a delay signal of the switch control signal,
wherein the frequency of a signal transmitted/received in an up link and in a down link is synthesized by using the oscillation signal.

2. The apparatus as claimed in claim 1, wherein the PLL synthesizer comprises:
a PLL circuit for generating an oscillation signal having the predetermined frequency; and
an isolation unit for isolating the oscillation signal from a signal that inversely flows from the RF switch, and for outputting an isolated oscillation signal.

3. The apparatus as claimed in claim 2, wherein the isolation unit comprises:
a capacitor for blocking a Direct Current (DC) signal that inversely flows from the RF switch; and
an isolator for shutting off noises that inversely flow from the RF switch.

4. The apparatus as claimed in claim 2, wherein the PLL circuit comprises:
a frequency divider for frequency-dividing an output signal from the PLL circuit;
a phase comparator for comparing a phase of the frequency-dividing signal with a phase of an input signal by using the reference clock signal, and for generating a phase difference signal;
a charge pump for controlling the quantity of output electric charges according to the phase difference signal;
a loop filter for low-pass filtering on an output of the charge pump, and for generating a frequency tuning voltage; and
a voltage controlled oscillator for generating the oscillating signal that oscillates with the predetermined frequency according to the frequency tuning voltage.

5. The apparatus as claimed in claim 1, wherein the alarm detector comprises:
a signal inducing unit for inducing the oscillation signal having the pre-determined frequency;
an RF detecting unit for converting the oscillation signal induced by the signal inducing unit into a DC level;
a filter for delaying the switch control signal by a time interval that determined based on a delay time during which the oscillation signal is settled as a normal signal; and
a comparing unit for generating an alarm detection signal by comparing an output signal of the RF detecting unit and an output signal of the filter.

6. The apparatus as claimed in claim 5, wherein the signal inducing unit comprises:
a coupler for inducing a signal from the oscillation signal passing the transmission path (Tx) or the receive path (Rx); and
a resistor pad for filtering the induced signal that flows into the coupler by using at least one resistor.

7. The apparatus as claimed in claim 6, wherein the coupler includes to a microstrip line adjacent to the transmission path (Tx) or the receive path (Rx) through which the oscillation signal passes.

8. The apparatus as claimed in claim 6, wherein the resistor pad comprises resistors arranged in the π form among an input, an output, and the ground.

9. The apparatus as claimed in claim 5, wherein the RF detecting unit comprises Schottky diodes.

10. The apparatus as claimed in claim 5, wherein the filter group-delays the switch control signal by using a Surface Acoustic Wave (SAW) filter.

11. The apparatus as claimed in claim 5, wherein the comparing unit integrates the output of the RF detecting unit in a case where the output of the filter is active, and outputs an integrated signal as the alarm detection signal.

12. The apparatus as claimed in claim 5, wherein the comparing unit comprises:
a first resistor having one terminal connected to an output end of the RF detecting unit;
a second resistor having one terminal connected to an output end of the filter;
an amplifier for receiving signals from the other terminals of the first and second resistors through first and second input terminals, and for outputting the alarm detection signal; and
a capacitor connected between the output end of the RF detecting unit and an output end of the amplifier.

13. The apparatus as claimed in claim 1, which further comprises a processor for generating the switch control signal, and for providing the switch control signal to the RF switch and the alarm detector.

14. The apparatus as claimed in claim 13, wherein the processor samples the alarm detection signal during an up link frame or during a down link frame except for gaps among link sections.

15. The apparatus as claimed in claim 13, wherein the processor samples the alarm detection signal, and determines if the oscillation signal provided by the RF switch is normal on the basis of the sampled signal.

16. A method for processing an oscillation signal in a wireless communication system supporting a Time Division Duplex (TDD) scheme, the method comprising the steps of:
(a) generating an oscillating signal phase-locked to a reference clock signal in a Phase-Locked Loop (PLL) circuit; and
(b) isolating the oscillating signal from a signal that flows from an RF switch by using a isolator connected to a capacitor, and outputting the isolated oscillation signal.

17. The method as claimed in claim 16, wherein step (a) comprises the steps of:
(a-1) comparing a phase of a signal obtained by frequency-dividing an output signal of the PLL circuit with a phase of an input signal generated by using the reference clock signal, and generating a frequency tuning voltage on the basis of a result of the comparing; and
(a-2) generating the oscillation signal that is phase-locked to the reference clock signal according to the frequency tuning voltage.

18. The method as claimed in claim 16, further comprising the steps of:
(c) outputting the isolated oscillation signal to a transmission path or a receive path by using an RF switch according to a switch control signal;
(d) inducing a signal from the oscillation signal, and converting the induced signal into a Direct Current (DC) level; and
(e) comparing a signal obtained by delaying the switch control signal for a pre-determined time interval with the signal converted into the DC level, and generating an alarm detection signal,
wherein steps (c), (d), and (e) follow step (b).

19. The method as claimed in claim 18, wherein step (a-1) comprises the step of;
generating the input signal by frequency-dividing the reference clock signal.

20. The method as claimed in claim 18, wherein in step (b), the induced signal is induced by being coupled to the oscillation signal passing the transmission path (Tx) or the receive path (Rx), and is filtered by at least one resistor.

21. The method as claimed in claim 18, wherein in step (e), the switch control signal is group-delayed for a time interval that determined based on a delay time during which the oscillation signal is selected and is settled as a normal signal.

22. The method as claimed in claim 18, wherein step (e) further comprises a step of integrating the signal converted into the DC level to output an integrated signal as the alarm detection signal in a case when the delayed switch control signal is active.

23. The method as claimed in claim 18, further comprising the steps of:
(f) sampling the generated alarm detection signal in a predetermined processor; and
(g) determining if the oscillation signal selected according to a sampled value is normal, in the predetermined processor,
wherein steps (f) and (g) follow step (e).

24. The method as claimed in claim 18, wherein the switch control signal is delayed for a time interval that determined based on a delay time during which the oscillation signal is settled as a normal signal.

25. A computer readable record medium storing a program for implementing the method according to claim 16.
